(19) United States
(12) Patent Application Publication
(10) Pub. No.: US 2025/0189567 A1
(43) Pub. Date: Jun. 12, 2025

(54) MEASURING THE PHASE OF A COMPLEX IMPEDANCE THROUGH THRESHOLDING

(71) Applicant: COMMISSARIAT A L’ENERGIE ATOMIQUE ET AUX ENERGIES ALTERNATIVES, PARIS (FR)

(72) Inventors: Esteban CABANILLAS, GRENOBLE (FR); Nicolas GARRAUD, GRENOBLE (FR); Julien MARIANNE, GRENOBLE (FR)

(21) Appl. No.: 18/972,488

(22) Filed: Dec. 6, 2024

(30) Foreign Application Priority Data
Dec. 7, 2023 (FR) 2313796

(51) Int. Cl. G01R 27/08

(52) U.S. Cl. CPC G01R 27/08

(57) ABSTRACT

A method for measuring the phase of the complex impedance of an electrical element (EL), including: applying an excitation signal at a known frequency to the electrical element (EL); acquiring a first and a second analog signal representative of a voltage and of a current, respectively; converting the first and the second analog signal to digital format; carrying out thresholding with hysteresis of the first and the second analog signal; measuring a time offset between an instant when the first analog signal and the second analog signal cross a threshold; and determining an estimate of the phase of the complex impedance of the electrical element as a function of the amplitudes of the first and the second analog signal converted to digital format, of the time offset and of the frequency of the excitation signal. A device for implementing this method is also provided.

### CROSS-REFERENCE TO RELATED APPLICATION

This application claims priority to foreign French patent application No. FR 2313796, filed on Dec. 7, 2023, the disclosure of which is incorporated by reference in its entirety.

### FIELD OF THE INVENTION

The invention lies in the field of electronic instrumentation. It relates more particularly to a method and a device for measuring a complex impedance of an electrical element.

### BACKGROUND

The concept of complex impedance generalizes that of resistance for sinusoidal signals at a given frequency f. In the case of an electric dipole, the complex impedance Z is defined by

$$Z = \frac{U}{I}$$

where U is the phasor (complex number) representing the amplitude and phase of the voltage across the terminals of the dipole and I is the phasor representing the amplitude and phase of the current flowing through it. More generally, in the case of an N-port circuit (the dipole corresponding to the case N=1), it is possible to define an impedance

$${Z}_{ij} = \frac{{U}_{i}}{{I}_{j}} {\vert}_{{I}_{k} = 0 , k \neq j} .$$

In other words, the impedance Zᵢⱼ is the (complex) ratio between the phasor representing the voltage across the terminals of the port “i” and the phasor representing the current entering (or exiting, depending on the convention adopted) the port “j” when the current entering all the other ports is zero. The various terms Zᵢⱼ form the impedance matrix of the multiport element. Hereinafter, the term impedance and the symbol “Z” will be used to designate both the impedance of a dipole and a term Zᵢⱼ of the impedance matrix of a multiport.

Being a complex number, the impedance Z may be broken down into a complex part and an imaginary part—Z=R+jX, where “j” here denotes the imaginary unit—or, in terms of modulus and phase: Z=|Z|e^{jφ}, where |Z| is the ratio between the RMS values of voltage and current and φ is their phase offset.

Generally speaking, impedance varies with the frequency of the electrical signals under consideration. To characterize an electrical element, it is therefore necessary to measure its (or their) impedance(s) in a more or less wide frequency band. Z(f), |Z(f)| and φ(f) are therefore written to designate, respectively, a complex impedance, its modulus and its phase as a function of the frequency f.

Many techniques have been developed to measure the phase of an impedance, φ(f), as a function of frequency.

(Angrisani 2001) discloses a measurement method in which a resistor of known value is connected in series to the element to be characterized and an excitation sinusoidal signal is applied to said element through this resistor. The impedance of the element to be characterized is able to be determined based on the measurement of the voltage u(t) of the excitation signal and the voltage v(t) of a node located between the known resistor and the element to be characterized. More particularly, two methods are proposed for determining the phase of said impedance:

Either the zero crossings of the signals u(t) and v(t) are detected, after having filtered these two signals by way of finite impulse response predictive filters in order to limit the impact of noise on zero detection;

Or the phase offset of the two signals is calculated based on their internal product and their mean square value.

(Schröder 2004) also determines the phase of a complex impedance by measuring the phase offset between two voltage signals. This phase offset measurement may be carried out by detecting zero crossings of said signals, or else through analytical calculation based on amplitude and phase parameters of said signals, determined by interpolation.

FR3009086 discloses a method and device for measuring the phase of the complex impedance of an electrical element. According to the teaching in that document, an excitation signal with a known frequency is applied to the electrical element, and then the phase offset between the current flowing through said device and the voltage across its terminals is measured. To measure this phase offset, comparators carry out thresholding of the voltage signals and current signals in order to convert them from a sinusoidal waveform to a square-wave one. A logic operation applied to the converted signals makes it possible to generate square waves the duration of which is proportional to the time offset between voltage and current. These square waves drive a switch that charges a capacitor. After a certain number of cycles, a voltage across the terminals of the capacitor is measured, this voltage being proportional to said offset. One drawback of this approach is its sensitivity to noise: indeed, when the threshold of the switches is close to being crossed, noise may induce multiple switching.

The solutions proposed by (Schröder 2004) and (Angrisani 2001) require carrying out relatively complex calculations and, in the case of (Angrisani 2001), implementing a specific power sensor.

### SUMMARY OF THE INVENTION

The invention aims to overcome at least some of the aforementioned drawbacks of the prior art. More specifically, it aims to make it possible to measure the phase of the impedance of an electrical element in a particularly simple way, implementing a device of low complexity, which may be based notably on a microcontroller or an FPGA.

One subject of the invention is a method for measuring the phase of the complex impedance of an electrical element, comprising the following steps:
a) applying an excitation signal oscillating at a known frequency f to said electrical element;
b) acquiring a first time-variable analog signal representative of a voltage across the terminals of the electrical element;
c) acquiring a second time-variable analog signal representative of a current through the electrical element;
d) determining a first numerical value representative of an amplitude of said first analog signal and a second numerical value representative of an amplitude of said second analog signal;
e) carrying out thresholding with hysteresis of said first and said second analog signal;
f) determining a third numerical value representative of a time offset between an instant when said first analog signal crosses a threshold and an instant when said second analog signal crosses said threshold or another threshold; and
g) determining an estimate of said phase of the complex impedance of the electrical element as a function of said first, second and third numerical values and of a fourth numerical value representative of the frequency f of the excitation signal.

In step e), the thresholding of the first analog signal may generate a first square-wave signal comprising a first rising edge and a first falling edge, and the thresholding of the second analog signal generates a second square-wave signal comprising a second rising edge and a second falling edge, and step f) may comprise a time-to-digital conversion operation carried out on a time offset between the first and the second rising edge, or between the first and the second falling edge.

Step g) comprises:
g1) determining a first approximation of said phase based on said third numerical value representative of a time offset and said fourth numerical value representative of the frequency f of the excitation signal;
g2) determining a phase correction term as a function of the first and the second numerical value;
g3) determining said estimate of the phase of the complex impedance of the electrical element by calculating the sum of said first approximation and said phase correction term.

According to particular embodiments of such a method:
Said fourth numerical value may be determined by calculating the product of said third numerical value representative of a time offset and said fourth numerical value representative of the frequency f of the excitation signal.
Said phase correction term may also be determined as a function of a fifth numerical value representative of a said threshold.
A phase correction term may be determined by way of a lookup table.

Another subject of the invention is a device for measuring the phase of a complex impedance of an electrical element, comprising:
a first analog-to-digital converter configured to receive, at input, a first time-variable analog signal representative of a voltage between two terminals of the electrical element, and convert it into a first digital signal;
a second analog-to-digital converter configured to receive a second time-variable analog signal representative of a current through the electrical element, and convert it into a second digital signal;
a first Schmitt trigger for generating a first square-wave signal by thresholding said first analog signal;
a second Schmitt trigger for generating a second square-wave signal by thresholding said second analog signal;
   and
a digital circuit configured to determine an estimate of said phase of the complex impedance of the electrical element as a function of a first numerical value representative of an amplitude of said first digital signal, of a second numerical value representative of an amplitude of said second digital signal, of a third numerical value representative of a time offset between the first square-wave signal and the second square-wave signal and of a fourth numerical value representative of the frequency f of the excitation signal.

Said digital circuit comprises:
a time-to-digital converter for determining said third numerical value;
a calculation module for determining a first approximation of said phase based on said third numerical value and on a fourth numerical value representative of a frequency f of said first and said second analog signal;
a lookup table for determining a phase correction term as a function of the first and the second numerical value; and
an adder module for determining said estimate of said phase of the complex impedance of the electrical element by calculating the sum of said first approximation and said phase correction term.

According to particular embodiments of such a device

The device may also comprise a third digital-to-analog converter for generating a fifth numerical value representative of a threshold voltage common to said first and second Schmitt trigger, said lookup table being configured to determine said phase correction term as a function of the first, the second and the fifth numerical value.

Said digital circuit may also be configured to receive said fifth numerical value at input.

### BRIEF DESCRIPTION OF THE DRAWINGS

Other features, details and advantages of the invention will become apparent on reading the description given with reference to the appended drawings, which are given by way of example, and in which, respectively:

FIG. 1 shows a block diagram of a measuring device not covered by the invention;

FIG. 2 shows an illustration of the operating principle of the device of [FIG. 1];

FIG. 3 shows an illustration of the phase measurement error caused by a difference in amplitude of the input signals;

FIG. 4 and FIG. 5 show graphs illustrating the dependence of said phase measurement error as a function of the threshold voltage for various amplitude values of the signal representative of the current through the electrical element and one and the same amplitude value of the signal representative of the voltage across its terminals; and

FIG. 6 shows a block diagram of a measuring device according to one embodiment of the invention.

### DETAILED DESCRIPTION

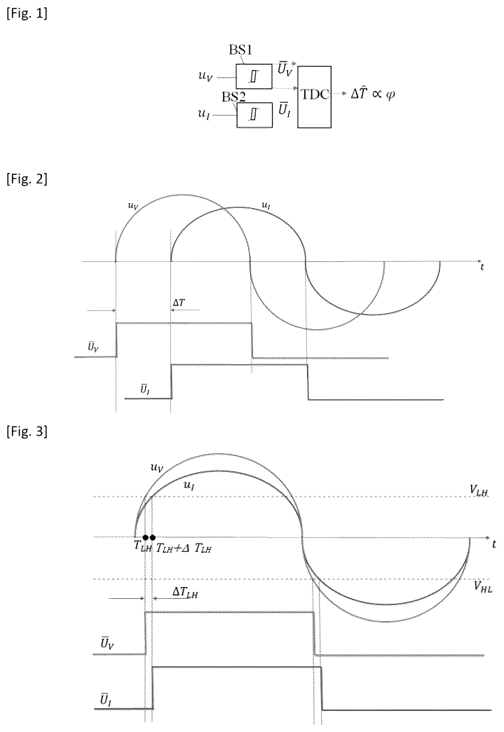

FIG. 1 is a block diagram of a hypothetical measuring device that makes it possible, in principle, to measure the phase offset between two sinusoidal analog signals u_{V} and u_{I}. If these two signals are representative, respectively, of the voltage across the terminals of an electrical element and of the current flowing through it, this phase offset measurement makes it possible to determine the phase of the complex impedance of the element.

The device of FIG. 1 comprises two Schmitt triggers BS1, BS2 having two threshold voltages V_{LH}>0 V and V_{HL}<0 V. The output of a Schmitt trigger goes to high when the signal at its input exceeds V_{LH}, and then remains high for as long as said signal falls below V_{HL}. For V_{LH}→0 V and V_{HL}→0 V, the Schmitt trigger becomes a simple zero comparator. If such a comparator were to be used, as in the case of document FR3009086 mentioned above, electronic noise would cause multiple and random switching during a zero crossing of the input signal; for this reason, it is generally preferred to use Schmitt triggers—also called hysteresis comparators—with a hysteresis ΔV=V_{LH}−V_{HL} of the same order of magnitude as the peak amplitude of the noise affecting the input signal.

The Schmitt triggers convert the input sinusoidal signals u_{V} and u_{I} into two square-wave signals Ū_{V} and Ū_{I}, respectively. A time-to-digital converter (TDC) receives these signals at input and supplies, at its output, a numerical value Δ\hat{T} that constitutes an estimate of the time offset ΔT between the rising edges (or, equivalently, the falling edges) of these signals. As may be seen in [FIG. 2], this time offset is in turn proportional to the phase offset φ between the two input analog signals u_{V} and u_{I}. Therefore, the digital output of the TDC converter constitutes (to within a multiplicative factor, equal to the frequency f of the input signals) an estimate \hat{φ} of this phase offset.

One drawback of using Schmitt triggers instead of simple zero comparators is that the instant when the threshold V_{LH} (or V_{HL} if the focus is on falling edges) is crossed does not depend solely on the phase of the input signals, but also on their amplitude. Therefore, a difference in amplitude of the signals u_{V} and u_{I} will distort the measurement of their phase offset. This is illustrated in the case of FIG. 3, where the signals u_{V} and u_{I} are perfectly in phase with one another, but not of the same amplitude. It may be seen that the most intense signal, u_{V}, crosses the threshold V_{LH} at a time t=T_{LH}, while the least intense signal, u_{I}, crosses it later, at an instant t=T_{LH}+ΔT_{LH}. The time offset ΔT_{LH} caused by the amplitude difference of u_{V} and u_{I} leads to a non-zero estimate @ of the phase offset between these two signals, which are actually in phase with one another. More precisely, \hat{φ}=Δ\hat{φ}_{LH}=fΔT_{LH} is found, f being the frequency of the input signals.

The situation does not change if the phase offset q between the two input signals is effectively non-zero: the difference between their amplitudes introduces an error in the estimation Δ\hat{φ}_{LH} of said phase offset.

The phase estimation error Δ\hat{φ}_{LH} may be calculated by analysing the signals around the time T_{LH}:

$${V}_{LH} = A cos ( ω {T}_{LH} ) ↔ {T}_{LH} = \frac{1}{ω} {cos}^{- 1} ( \frac{{V}_{LH}}{A} ) \qquad ( 1 )$$

$${V}_{LH} = B cos ( ω ( {T}_{LH} + Δ {T}_{LH} ) ) ↔ Δ {T}_{LH} = \frac{1}{ω} ( {cos}^{- 1} ( \frac{{V}_{LH}}{B} ) ) - {T}_{LH} \qquad ( 2 )$$

where A and B are the (real) amplitudes of the sinusoidal analog signals u_{V} and u_{I}, and ω is the angular frequency of the signals, ω=2πf.

Removing T_{LH} from the above two equations gives:

$$Δ {T}_{LH} = \frac{1}{ω} ( {cos}^{- 1} ( \frac{{V}_{LH}}{B} ) - {cos}^{- 1} ( \frac{{V}_{LH}}{A} ) ) \qquad ( 3 )$$

The phase error Δφ_{LH} is therefore given by:

$$Δ {\hat{φ}}_{LH} = {cos}^{- 1} ( \frac{{V}_{LH}}{B} ) - {cos}^{- 1} ( \frac{{V}_{LH}}{A} ) \qquad ( 4 )$$

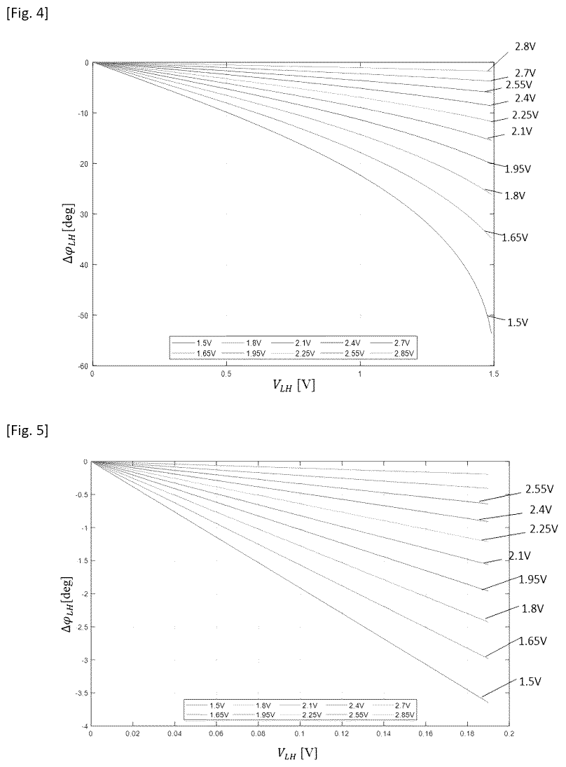

FIG. 4 is a graph of the phase error Δφ_{LH} as a function of the threshold voltage V_{LH} for various values of the amplitude B ranging from 1.5 V to 2.85 V, while the amplitude A is considered to be fixed at 3 V. In the case where the signal-to-noise ratio (SNR) of the input signals is not excessively high—for example SNR>25 dB—it is possible to adopt a low value of V_{LH} compared to A and B, for example V_{LH}<0.2 V. Under these conditions, Δφ_{LH} may be approximated by a linear function, as illustrated by FIG. 5.

Indeed, developing the expression of Δφ_{LH} obtained above into a first-order Taylor series around V_{LH}=0 gives

$$Δ {\hat{φ}}_{LH} = {cos}^{- 1} ( \frac{{V}_{LH}}{B} ) - {cos}^{- 1} ( \frac{{V}_{LH}}{A} ) ∼ ( \frac{π}{2} - \frac{{V}_{LH}}{B} ) - ( \frac{π}{2} - \frac{{V}_{LH}}{A} ) = \frac{{V}_{LH}}{A} - \frac{{V}_{LH}}{B} = ( \frac{1}{A} - \frac{1}{B} ) {V}_{LH} \qquad ( 5 )$$

One idea on which the invention is based is that the error Δφ_{LH} may be calculated beforehand as a function of the amplitudes A and B and of the threshold voltage V_{LH}, quantities that are able to be measured easily using analog-to-digital converters (V_{LH} may also be considered to be known by design of the system). This makes it possible to compensate for said error so as to obtain an improved estimate of the phase offset between the input signals:

$$\hat{{φ}^{′}} = \hat{φ} - Δ {\hat{φ}}_{LH} \qquad ( 6 )$$

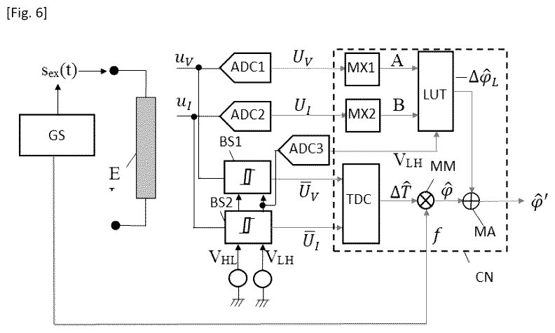

FIG. 6 illustrates a block diagram of a device according to one embodiment of the invention, implementing this principle.

In FIG. 6, the reference EL represents an electrical element (more particularly a dipole comprising two terminals forming a single port) for which the phase of the complex impedance is to be determined. A generator GS applies a sinusoidal excitation signal sₑₓₜ(t) of possibly variable frequency f to the terminals of the element EL. The signal sₑₓₜ(t) may be a current signal or a voltage signal. The generator GS also supplies, at its output, a numerical value representative of the frequency f. The generator GS may for example be driven in such a way that f scans, continuously or discretely, a spectral band of interest.

The device of FIG. 6 receives, on a first input port, the first analog signal u_{V}(t) representative of the voltage across the terminals of the element EL and, on a second input port, the second analog signal u_{I}(t) representative of the current flowing through it. For example, the signal u_{V}(t) may directly be the voltage across the terminals of the element EL and u_{I}(t) may be a voltage across the terminals of a resistor connected in series to EL. A first analog-to-digital converter ADC1 samples the analog signal u_{V} and converts it into a digital signal U_{V}. Similarly, a second analog-to-digital converter ADC2 samples the analog signal u_{I} and converts it into a digital signal U_{I}.

The signals u_{V}(t) and u_{I}(t) are also supplied at input to respective Schmitt triggers BS1, BS2, which supply square-wave signals Ū_{V}, Ū_{I} at output. As explained above, with reference to FIG. 2 and FIG. 3, the rising edges of these square-wave signals correspond to u_{V}(t) and u_{I}(t), respectively, crossing a threshold V_{LH} in the rising direction, whereas their falling edges correspond to these same signals crossing a threshold V_{HL}<V_{LH} in the falling direction. The thresholds V_{HL} and V_{LH} are set by voltage values supplied at input to the Schmitt triggers BS1, BS2. The voltage V_{LH}, moreover, is converted to digital format by a third analog-to-digital converter ADC3.

The digital signals U_{V}, U_{I}, V_{TH} and f, along with the square-wave signals Ū_{V}, Ū_{I}, are supplied at input to a digital circuit CN that uses them to calculate an estimate \hat{φ}′ of the phase offset between the signals u_{V}(t) and u_{I}(t)—that is to say of the phase of the complex impedance of the electrical element EL.

The digital circuit CN comprises a time-to-digital converter TDC that receives, at input, the square-wave signals Ū_{V}, Ū_{I} and—as explained above with reference to FIG. 1—generates a numerical value Δ\hat{T} representative of a time offset between their rising edges. A multiplier module MM calculates the product of Δ\hat{T} and the frequency f in order to determine a first estimate \hat{φ} of the phase offset φ between the signals u_{V}(t) and u_{I}(t), and therefore of the phase of the complex impedance of the element EL.

The digital circuit CN also comprises two logic blocks MX1, MX2 configured to extract, from the digital signals U_{V} and U_{I}, the values A and B representative of the amplitude of the analog signals u_{V}(t) and u_{I}(t). For example, the blocks MX1, MX2 are able to determine local extrema of said signals and average their values, or interpolate them with perfect sinusoidal functions.

The numerical values A, B and V_{LH} (the latter coming from the third analog-to-digital converter ADC3) make it possible to calculate the correction term −Δ\hat{φ}_{LH} by applying equation (4), its linear approximation (5) or a polynomial approximation. The calculation is typically performed using a three-entry lookup table LUT.

Finally, an adder module MA calculates a corrected estimate \hat{φ}′ by applying the correction term −Δ\hat{φ}_{LH} to the first estimate \hat{φ}.

The invention has been described with reference to one particular embodiment, but variants are possible. For example:

The digital circuit CN may be implemented by way of a microprocessor programmed in a timely manner (in which case the various “blocks” and “modules” of FIG. 6 are implemented in the form of software), an FPGA or an ASIC.

The lookup table LUT may be implemented by way of a dedicated memory device, or constitute a region of a memory of a microprocessor.

The correction term −Δ\hat{φ}_{LH} may be determined by an arithmetic circuit (in the case of an FPGA or ASIC implementation) or by a calculation routine (in the case of a software implementation), rather than a lookup table, particularly if the linear approximation of equation (5) is used.

The blocks MX1, MX2 may be omitted if a peak detector is provided upstream of each of the analog-to-digital converters ADC1, ADC2.

Rather than the time offset between the rising edges of the signals U_{V} and U_{I}, it is possible to take into account the falling edges. In this case, it is the threshold V_{HL} that should be used to calculate the correction term.

The value of the threshold V_{LH} (or V_{HL} if the focus is on falling edges) may be predefined and stored in a memory, rather than being acquired and converted to digital format. The use of an analog-to-digital converter ADC3, as in the embodiment of FIG. 3, is however advantageous because it makes it possible to take account of drift.

Similarly, the frequency f may be a predefined value stored in a memory, rather than being supplied by the generator FS. Conversely, it may also be determined based on the analog signals u_{V}(t) and u_{I}(t).

Many embodiments known to those skilled in the art are possible for the time-to-digital converter TDC: a simple high-frequency counter, a counter with a delay line, a dual delay line circuit, etc.

### REFERENCES

(Angrisani 2001): L. Angrisani, L. Ferrigno, Reducing the uncertainty in real-time impedance measurements, Measurement, Volume 30, Issue 4, 2001, pages 307-315,
(Schröder 2004): Jens Schröder and Steffen Doerner and Thomas Schneider and Peter Hauptmann, Analogue and digital sensor interfaces for impedance spectroscopy, Measurement Science and Technology, Volume 15, Issue 7, 2004, pages 1271-1278

1. A method for measuring the phase of the complex impedance of an electrical element (EL), comprising the following steps:
a) applying an excitation signal (Sex) oscillating at a known frequency f to said electrical element (EL);
b) acquiring a first time-variable analog signal (u_{V}) representative of a voltage across the terminals of the electrical element;
c) acquiring a second time-variable analog signal (u_{I}) representative of a current through the electrical element;
d) determining a first numerical value (A) representative of an amplitude of said first analog signal (u_{V}) and a second numerical value (B) representative of an amplitude of said second analog signal (u_{I});
e) carrying out thresholding with hysteresis of said first and said second analog signal;
f) determining a third numerical value (Δ\hat{T}) representative of a time offset between an instant when said first analog signal crosses a threshold and an instant when said second analog signal crosses said threshold or another threshold; and
g) determining an estimate (\hat{φ}′) of said phase of the complex impedance of the electrical element as a function of said first, second and third numerical values and of a fourth numerical value representative of the frequency f of the excitation signal; wherein step g) comprises:
g1) determining a first approximation (\hat{φ}) of said phase (φ) based on said third numerical value (Δ\hat{T}) representative of a time offset and on said fourth numerical value representative of the frequency f of the excitation signal;
g2) determining a phase correction term (−Δφ_{LH}) as a function of the first and the second numerical value;
g3) determining said estimate ( [symbol] ) of the phase of the complex impedance of the electrical element by calculating the sum of said first approximation and said phase correction term.

2. The method as claimed in claim 1, wherein, in step e), the thresholding of the first analog signal generates a first square-wave signal (Ū_{V}) comprising a first rising edge and a first falling edge, and the thresholding of the second analog signal generates a second square-wave signal (Ū_{I}) comprising a second rising edge and a second falling edge, and wherein step f) comprises a time-to-digital conversion operation carried out on a time offset (ΔT_{LH}) between the first and the second rising edge, or between the first and the second falling edge.

3. The method as claimed in claim 1, wherein said fourth numerical value is determined by calculating the product of said third numerical value (Δ\hat{T}) representative of a time offset and said fourth numerical value representative of the frequency f of the excitation signal.

4. The method as claimed in claim 1, wherein said phase correction term (−Δφ_{LH}) is also determined as a function of a fifth numerical value (V_{LH}) representative of a said threshold.

5. The method as claimed in claim 1, wherein a phase correction term (−Δφ_{LH}) is determined by way of a lookup table (LUT).

6. A device for measuring the phase of a complex impedance of an electrical element (EL), comprising:
a first analog-to-digital converter (ADC1) configured to receive, at input, a first time-variable analog signal (u_{V}) representative of a voltage between two terminals of the electrical element, and convert it into a first digital signal (U_{V});
a second analog-to-digital converter (ADC2) configured to receive a second time-variable analog signal (u_{I}) representative of a current through the electrical element, and convert it into a second digital signal (U_{I});
a first Schmitt trigger (BS1) for generating a first square-wave signal (Ū_{V}) by thresholding said first analog signal;
a second Schmitt trigger (BS2) for generating a second square-wave signal (Ū_{I}) by thresholding said second analog signal; and
a digital circuit (CN) configured to determine an estimate (\hat{φ}′) of said phase of the complex impedance of the electrical element as a function of a first numerical value (A) representative of an amplitude of said first digital signal (U_{V}), of a second numerical value (B) representative of an amplitude of said second digital signal (U_{I}), of a third numerical value (ΔT) representative of a time offset between the first square-wave signal (Ū_{V}) and the second square-wave signal (Ū_{V}) and of a fourth numerical value representative of the frequency f of the excitation signal;
wherein said digital circuit comprises:
a time-to-digital converter (TDC) for determining said third numerical value (Δ\hat{T});
a calculation module for determining a first approximation (\hat{φ}) of said phase (φ) based on said third numerical value (Δ\hat{T}) and on a fourth numerical value representative of a frequency f of said first and said second analog signal;
a lookup table for determining a phase correction term (−Δφ_{LH}) as a function of the first and the second numerical value; and
an adder module for determining said estimate (\hat{φ}′) of said phase of the complex impedance of the electrical element by calculating the sum of said first approximation and said phase correction term.

7. The device as claimed in claim 6, also comprising a third digital-to-analog converter (ADC3) for generating a fifth numerical value (V_{LH}) representative of a threshold voltage common to said first and second Schmitt trigger, said lookup table (LUT) being configured to determine said phase correction term (−Δφ_{LH}) as a function of the first, the second and the fifth numerical value.

8. The device as claimed in claim 6, wherein said digital circuit (CN) is also configured to receive said fifth numerical value (V_{LH}) at input.

9. The device as claimed in claim 7, wherein said digital circuit (CN) is also configured to receive said fifth numerical value (V_{LH}) at input.
